(19) United States
(12) Patent Application Publication
(10) Pub. No.: US 2025/0234648 A1
(43) Pub. Date: Jul. 17, 2025

(54) ARRAY SUBSTRATE

(71) Applicant: Sharp Display Technology Corporation, Kameyama City (JP)

(72) Inventor: Masatomo HONJO, Kameyama City (JP)

(21) Appl. No.: 19/001,749

(22) Filed: Dec. 26, 2024

(30) Foreign Application Priority Data
Jan. 12, 2024 (JP) 2024-003089

(51) Int. Cl. H10D 86/40

(52) U.S. Cl. CPC H10D 86/441; H10D 86/451; H10D 86/423

(57) ABSTRACT

An array substrate includes gate lines extending in a first direction and being portions of a gate metal film, source lines extending in a second direction and being portions of a source metal film, and first and second TFTs arranged alternately in the first direction. The first TFTs include first semiconductor portions that are portions of a first semiconductor film, first gate electrodes that are portions of the gate metal film, and first source electrodes and first drain electrodes that are portions of the source metal film. The second TFTs include second semiconductor portions that are portions of a second semiconductor film above the first semiconductor film via an insulating film, second gate electrodes that are portions of the gate metal film, and second source electrodes and second drain electrodes that are portions of the source metal film. The first and second semiconductor portions are alternately arranged.

### CROSS REFERENCE TO RELATED APPLICATION

This application claims priority from Japanese Patent Application No. 2024-003089 filed on Jan. 12, 2024. The entire contents of the priority application are incorporated herein by reference.

### TECHNICAL FIELD

The present technology described herein relates to an array substrate.

### BACKGROUND

It has been known that thin film transistors (TFTs) are used as switching components in a display panel such as a liquid crystal panel and an organic electro-luminescence (EL) panel. It has been known that the TFTs are formed by disposing various kinds of thin films in layers on an array substrate (an active matrix substrate, a TFT substrate) of the display panel with photolithography.

One example of such array substrates includes a first TFT and a second TFT that are disposed in layers with respect to a vertical direction with respect to the surface of the substrate in a pixel section. More specifically, a gate electrode, a gate insulating film, a semiconductor film, a source electrode, and a drain electrode of the second TFT are disposed on a gate electrode, a gate insulating film, a semiconductor film, a source electrode, and a drain electrode of the first TFT. With such a configuration, a planar area where the TFTs are disposed is decreased and light transmittance and an opening ratio can be increased.

With such a configuration, the intervals between the pixels can be decreased and high resolution of the display panel can be achieved; however, the number of layers of the thin films is greatly increased and the production process becomes longer.

### SUMMARY

The technology described herein was made in view of the above circumstances. An object is to obtain an array substrate having small intervals between pixels without increasing the number of layers of thin films.

(1) An array substrate according to the technology described herein includes an insulating substrate, gate lines disposed on an upper layer side of the insulating substrate and extending in a first direction, the gate lines being portions of a gate metal film, source lines extending in a second direction that crosses the first direction, the source lines being portions of a source metal film, and first TFTs and second TFTs arranged alternately in the first direction in a plan view. The first TFTs include first semiconductor portions that are portions of a first semiconductor film and arranged in the first direction, first gate electrodes that are portions of the gate metal film, and first source electrodes and first drain electrodes that are portions of the source metal film. The second TFTs include second semiconductor portions that are portions of a second semiconductor film that is disposed in a layer upper than a layer including the first semiconductor film via an insulating film, the second semiconductor portions and the first semiconductor portions being arranged alternately in the first direction, second gate electrodes that are portions of the gate metal film, and second source electrodes and second drain electrodes that are portions of the source metal film.

(2) In the array substrate, in addition to (1), the first semiconductor portions may have a first dimension extending in the first direction, the second semiconductor portions may have a second dimension extending in the first direction, and the first dimension may be different from the second dimension.

(3) In the array substrate, in addition to (1) or (2), the second semiconductor portions may have a thickness that is different from a thickness of the first semiconductor portions.

(4) In the array substrate, in addition to any one of (1) to (3), the second semiconductor portions may be made of material that has a composition different from a composition of material of the first semiconductor portions.

(5) In the array substrate, in addition to any one of (1) to (4), the first semiconductor portions may have a third dimension extending in the second direction, the second semiconductor portions may have a fourth dimension extending in the second direction, and the third dimension may be different from the fourth dimension.

(6) In the array substrate, in addition to any one of (1) to (5), the first TFTs and the second TFTs may be arranged alternately in the second direction in a plan view, and one of the second semiconductor portions may be disposed between two of the first semiconductor portions that are adjacent to each other in the second direction in a plan view.

(7) In the array substrate, in addition to any one of (1) to (6), the gate metal film may be included in a layer upper than layers including the first semiconductor film and the second semiconductor film.

(8) In the array substrate, in addition to any one of (1) to (6), the gate metal film may be included in a layer lower than layers including the first semiconductor film and the second semiconductor film.

(9) In the array substrate, in addition to any one of (1) to (8), the first semiconductor film and the second semiconductor film may be made of oxide semiconductor material that includes at least one kind of metallic elements of In, Ga, and Zn.

(10) In the array substrate, in addition to (9), the first semiconductor portions may have a first dimension extending in the first direction, the second semiconductor portions may have a second dimension extending in the first direction, and the first dimension may be greater than the second dimension.

(11) In the array substrate, in addition to one of (9) and (10), a content of the at least one kind of metallic elements of In, Ga, and Zn in the first semiconductor film may be greater than that in the second semiconductor film.

According to the technology described herein, an array substrate having small intervals between pixels is obtained without increasing the number of layers of thin films.

### BRIEF DESCRIPTION OF THE DRAWINGS

FIG. 1 is a plan view illustrating a liquid crystal panel according to a first embodiment.

FIG. 2 is a cross-sectional view of the liquid crystal panel.

FIG. 3 is a circuit diagram illustrating a pixel arrangement of an array substrate in a display area.

FIG. 4 is a plan view illustrating a layout pattern of the array substrate in the display area.

FIG. 5 is a plan view illustrating gate lines and semiconductor portions in FIG. 4.

FIG. 6 is a cross-sectional view along I-I line in FIG. 4.

FIG. 7 is a cross-sectional view along II-II line in FIG. 4.

FIG. 8 is a cross-sectional view along III-III line in FIG. 5.

FIG. 9 is a plan view illustrating a layout pattern of semiconductor portions according to a second embodiment.

FIG. 10 is a cross-sectional view along IV-IV line in FIG. 9.

FIG. 11 is a plan view illustrating a layout pattern of semiconductor portions according to a third embodiment.

FIG. 12 is a cross-sectional view of a portion near a first TFT according to other embodiment.

FIG. 13 is a cross-sectional view of a portion near a second TFT according to other embodiment.

FIG. 14 is a plan view illustrating a layout pattern of semiconductor portions according to other embodiment.

FIG. 15 is a plan view illustrating a layout pattern of semiconductor portions according to other embodiment.

### DETAILED DESCRIPTION

### First Embodiment

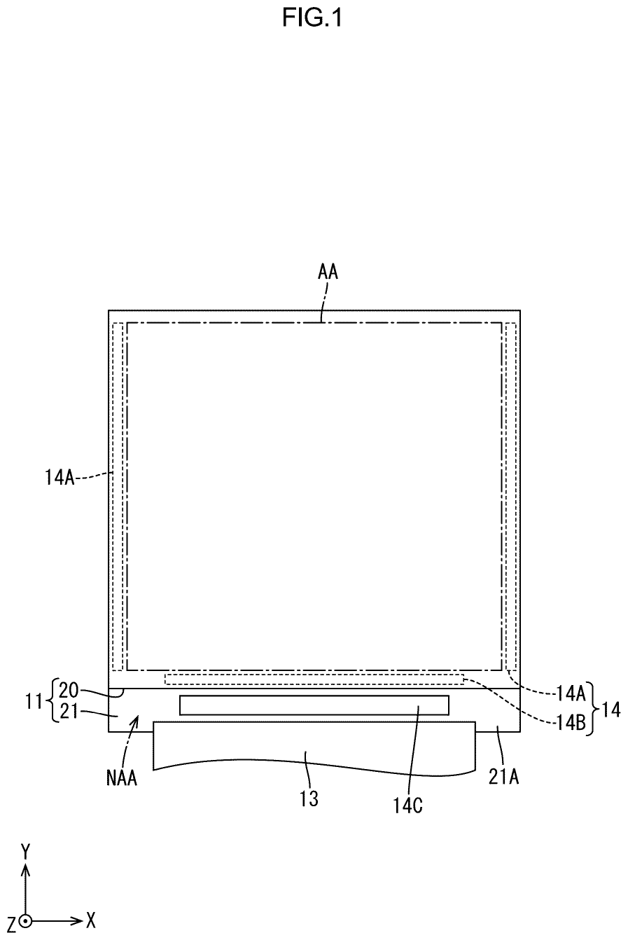

A liquid crystal panel 11 (one example of a display panel) according to a first embodiment will be described with reference to FIGS. 1 to 8. X-axes, Y-axes, and Z-axes may be present in the drawings. The axes in each drawing correspond to the respective axes in other drawings.

As illustrated in FIG. 1, an inner surface of the liquid crystal panel 11 is divided into a display area AA (an active area) and a non-display area NAA (a non-active area). The display area AA is a middle section of the inner surface and images are displayed on the display area AA. The non-display area NAA is an outer section in a frame plan view shape surrounding the display area AA. In FIG. 1, the outline of the display area AA is illustrated with a chain line and an area outside the chain line is the non-display area NAA. The planar shape of the liquid crystal panel 11 is not limited to a special shape. In this embodiment, the liquid crystal panel 11 has a vertically long rectangular shape as a whole. A short-side direction corresponds to the X-axis direction, a long-side direction corresponds to the Y-axis direction, and a thickness direction corresponds to the Z-axis direction.

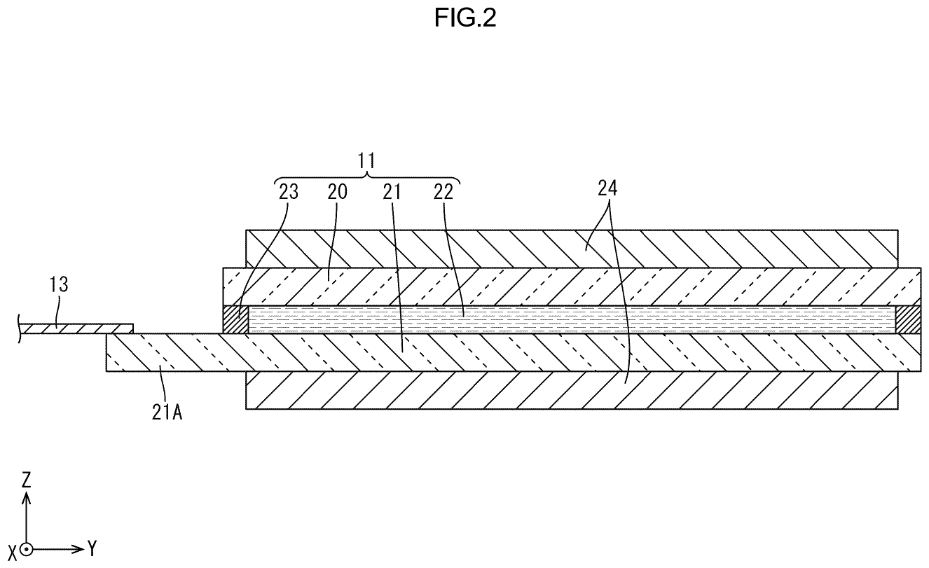

As illustrated in FIG. 2, the liquid crystal panel 11 includes a pair of substrates 20, 21 that are bonded to each other. At least a liquid crystal layer 22 and a sealing portion 23 for sealing the liquid crystal layer 22 are disposed between the substrates 20 and 21. The liquid crystal layer 22 includes liquid crystal molecules having optical characteristics that vary according to application of electric field. The sealing portion 23 is formed in a rectangular frame shape as a whole in a plan view and surrounds the liquid crystal layer 22 in the non-display area NAA. A gap (a cell gap) corresponding to a thickness of the liquid crystal layer 22 can be maintained by the sealing portion 23. Polarizing plates 24 are attached to outer surfaces of the substrates 20 and 21.

One of the substrates 20, 21 on the front side (a display surface side) is an opposed substrate 20 (a CF substrate) and another one on the back side is an array substrate 21 (an active matrix substrate, a TFT substrate). The opposed substrate 20 and the array substrate 21 include glass substrates that are almost transparent and have good light transmissive properties and various kinds of films that are formed in layers on an inner surface side the glass substrates (on surfaces opposite the liquid crystal layer 22).

A backlight unit that supplies light to the liquid crystal panel 11 is disposed behind the liquid crystal panel 11 (opposite the array substrate 21). The liquid crystal panel 11 of this embodiment is used for a head-mount display, for example, and has quite high resolution. The pixel density of the liquid crystal panel 11 is from 1000 ppi to 1800 ppi, for example.

The array substrate 21 is larger in size than the opposed substrate 20 and a portion of the array substrate 21 projects from an edge of the opposed substrate 20. A flexible substrate 13 is mounted on a projecting portion 21A of the array substrate 21. The flexible substrate 13 includes a base having insulating properties and flexibility and multiple traces formed on the base. A first end of the flexible substrate 13 is connected to the array substrate 21 and a second end of the flexible substrate 13 is connected to an external control board (a signal supply). Various kinds of signals supplied from the control board are transmitted to the liquid crystal panel 11 via the flexible substrate 13.

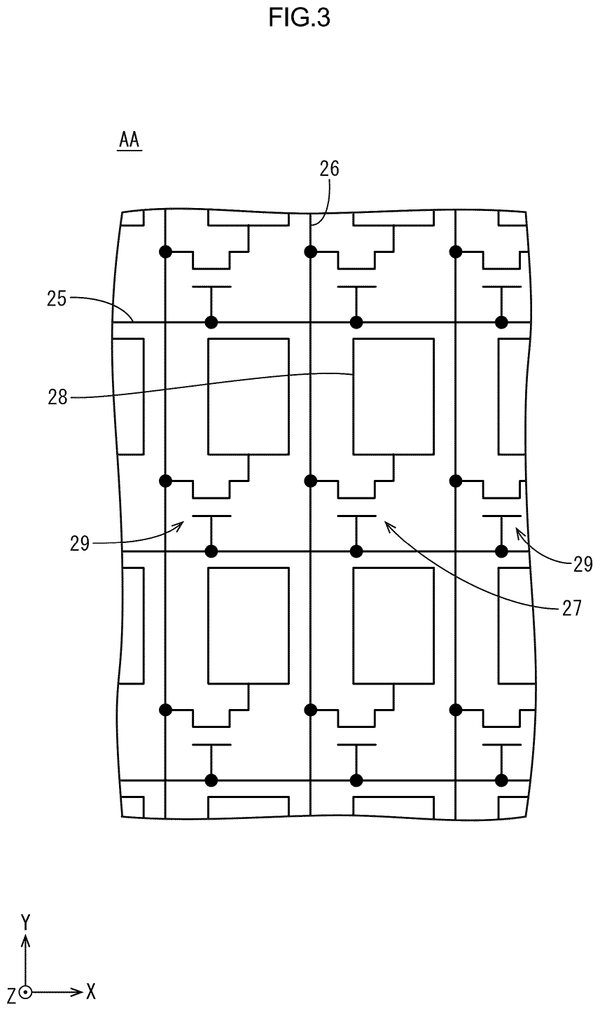

As illustrated in FIG. 3, gate lines 25 (scan lines) and source lines 26 (image lines) are arranged in a grid in the display area AA of the array substrate 21. The gate lines 25 extend in a direction substantially along the X-axis direction (one example of a first direction) and cross laterally the display area AA. The gate lines 25 are arranged at intervals in the Y-axis direction. The gate lines 25 are supplied with scan signals output from first circuits 14A. The source lines 26 extend in a direction substantially along the Y-axis direction (one example of a second direction) and cross vertically the display area AA. The source lines 26 cross the gate lines 25. The source lines 26 are arranged at intervals in the X-axis direction. The source lines 26 are supplied with image signals output from a second circuit 14B.

A pixel electrode 28 and one of a first TFT 27 and a second TFT 29 are disposed near a crossing portion of the gate line 25 and the source line 26. The first TFTs 27, the second TFTs 29, and the pixel electrodes 28 are arranged regularly along the X-axis direction and the Y-axis direction. The first TFTs 27 and the second TFTs 29 are arranged alternately along the X-axis direction. Each of the first TFT 27 and the second TFT 29 is connected to the gate line 25, the source line 26, and the pixel electrode 28. With each of the first TFT 27 and the second TFT 29 being driven based on the scan signal supplied to the gate line 25, the pixel electrode 28 is charged at the potential related to the image signal supplied to the source line 26. The first TFTs 27 and the second TFTs 29 are switching components.

As illustrated in FIG. 1, circuits 14 (a surrounding circuit) are disposed in the non-display area NAA of the array substrate 21. The circuits 14 include the first circuits 14A and the second circuit 14B. Two first circuits 14A are disposed to sandwich the display area AA with respect to the X-axis direction; however, one first circuit 14A may be disposed on only one side. The first circuit 14A is a gate driver monolithic (GDM) circuit that is configured to supply scan signals to the gate lines 25. The second circuit 14B is disposed between the display area AA and the flexible substrate 13 in the Y-axis direction. The second circuit 14B is configured to distribute the image signals (source signals), which are supplied from a source driver 14C, to the source lines 26.

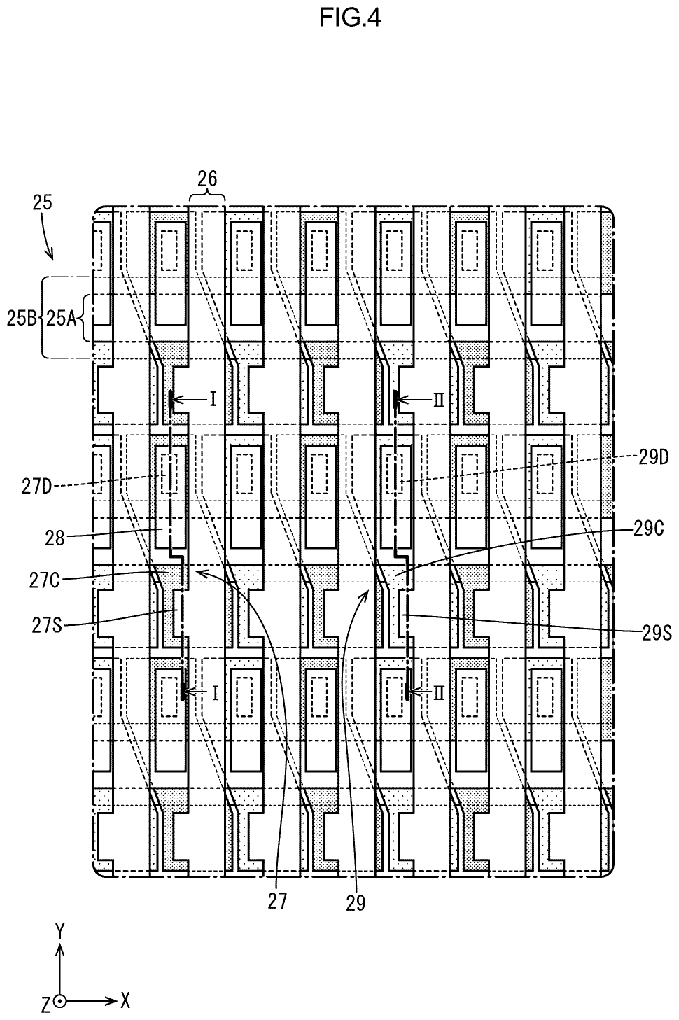

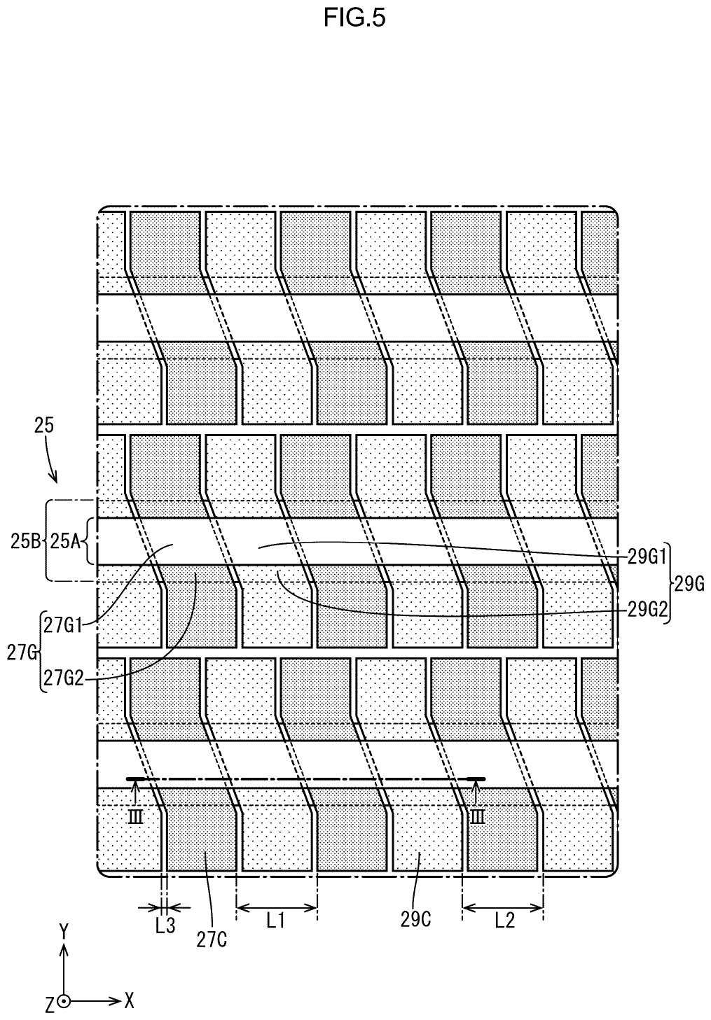

Next, a planar layout pattern of the array substrate 21 in the display area AA will be described with reference to FIGS. 4 and 5. As illustrated in FIG. 4, the pixel electrode 28 is disposed in a section surrounded by the two gate lines 25, which are spaced from each other in the Y-axis direction, and the two source lines 26, which are spaced from each other in the X-axis direction. The pixel electrode 28 has a vertically elongated rectangular plan view shape corresponding to the planar shape of the section. The source lines 26 have wide sections that are configured as first source electrodes 27S of the first TFTs 27 and second source electrodes 29S of the second TFTs 29.

The first TFT 27 includes a first semiconductor portion 27C, a first gate electrode 27G, a first source electrode 27S, and a first drain electrode 27D. The second TFT 29 includes a second semiconductor portion 29C, a second gate electrode 29G, a second source electrode 29S, and a second drain electrode 29D.

The gate line 25 includes a top gate line 25A and a bottom gate line 25B. The top gate line 25A is included in a layer upper than the layers including the first semiconductor portions 27C and the second semiconductor portions 29C. The bottom gate line 25B is included in a layer lower than the layers including the semiconductor portions 27C and the second semiconductor portions 29C. The top gate line 25A is narrower than the bottom gate line 25B and overlaps the bottom gate line 25B. The top gate line 25A is disposed on a middle portion of the bottom gate line 25B. The top gate line 25A and the bottom gate line 25B are connected to each other. The scan signal supplied to the gate line 25 is supplied to the top gate line 25A and the bottom gate line 25B and the top gate line 25A and the bottom gate line 25B have a same potential. The gate line 25 may not include the bottom gate line 25B and include only the top gate line 25A.

As illustrated in FIG. 5, portions of the top gate line 25A that overlap the first semiconductor portions 27C are configured as first top gate electrodes 27G1 and portions of the top gate line 25A that overlap the second semiconductor portions 29C are configured as second top gate electrodes 29G1. Portions of the bottom gate line 25B that overlap the first semiconductor portions 27C are configured as first bottom gate electrodes 27G2 and portions of the bottom gate line 25B that overlap the second semiconductor portions 29C are configured as second bottom gate electrodes 29G2. As illustrated in FIG. 4, the first drain electrode 27D and the second drain electrode 29D are disposed to overlap the pixel electrodes 28, respectively, and disposed on an opposite side with respect to the gate line 25 (portions of which are configured as the first gate electrode 27G and the second gate electrode 29G) from the first source electrode 27S and the second source electrode 29S, respectively, in the Y-axis direction.

A first end portion of the first semiconductor portion 27C and a first end portion of the second semiconductor portions 29C are connected to the first source electrode 27S and the second source electrode 29S, respectively. A second end portion of the first semiconductor portion 27C and a second end portion of the second semiconductor portions 29C are connected to the first drain electrode 27D and the second drain electrode 29D, respectively. As illustrated in FIG. 5, the first semiconductor portion 27C and the second semiconductor portion 29C have a vertically elongated plan view shape as a whole. The first semiconductor portion 27C and the second semiconductor portion 29C are bent such that portions of the first semiconductor portion 27C and the second semiconductor portion 29C overlapping the gate line 25 (portions of which are configured as the first gate electrode 27G and the second gate electrode 29G) are inclined with respect to the Y-axis direction.

In this embodiment, the first semiconductor portion 27C and the second semiconductor portion 29C have a same planar shape and a same planar size but may have different planar shape and size. The second semiconductor portion 29C is disposed between the first semiconductor portions 27C in a plan view. The first semiconductor portions 27C are portions of a first semiconductor film and are arranged in the X-axis direction at intervals L1. The second semiconductor portions 29C are portions of a second semiconductor film that is disposed in a layer different from a layer including the first semiconductor film. The second semiconductor portions 29C are arranged in the X-axis direction at intervals L2.

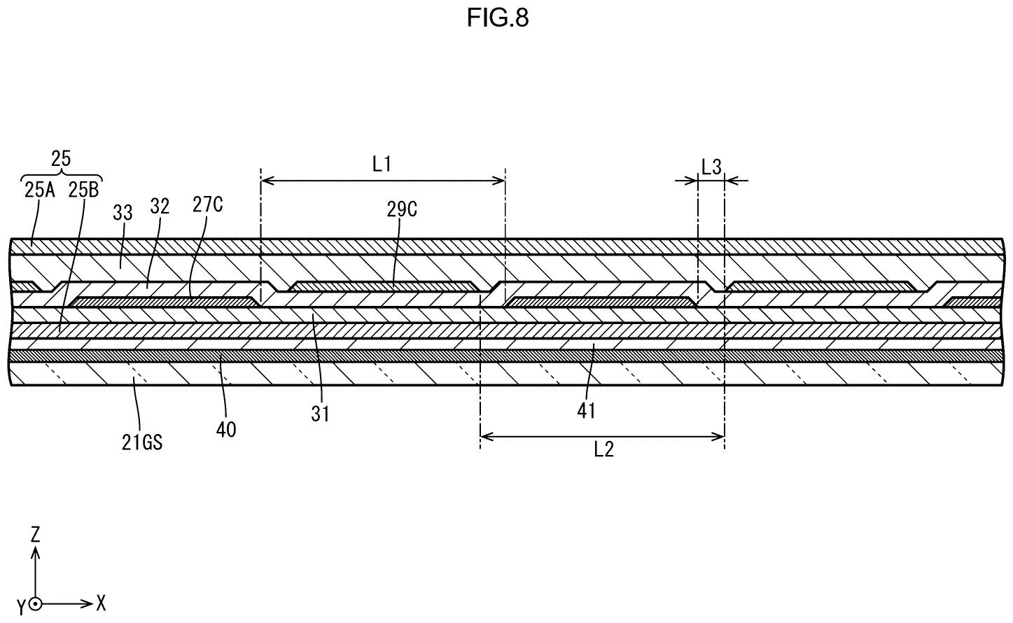

Therefore, as illustrated in FIG. 8, the first semiconductor portions 27C and the second semiconductor portions 29C are portions of different semiconductor films (the first semiconductor film, the second semiconductor film) and are alternately disposed in different layers. With such a configuration, an interval L3 between the first semiconductor portion 27C and the second semiconductor portion 29C, which are adjacent to each other, is much smaller than the interval L1 between the first semiconductor portions 27C and the interval L2 between the second semiconductor portions 29C (L3<L1 and L3<L2). In this embodiment, the interval L1 and the interval L2 are same but may be different.

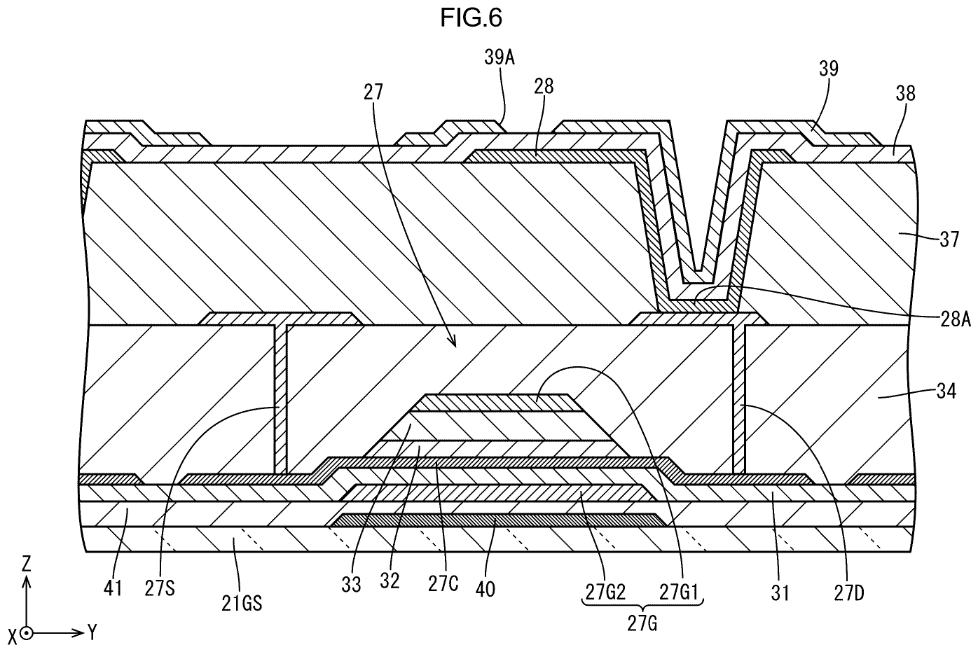

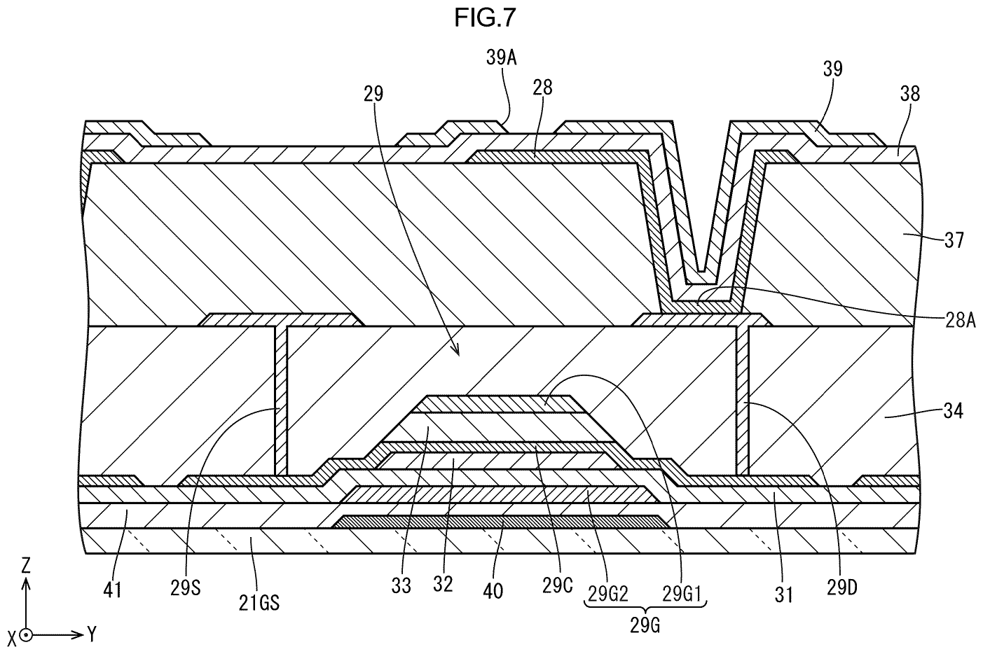

Next, a cross-sectional configuration of the array substrate 21 will be described in detail with reference to FIGS. 6 to 8. In the display area AA of the array substrate 21, the first TFTs 27 have a configuration as illustrated in FIG. 6 and the second TFTs 29 have a configuration as illustrated in FIG. 7. The first semiconductor portion 27C is disposed between the first top gate electrodes 27G1 and the first bottom gate electrode 27G2 with respect to the upper-bottom direction. The second semiconductor portion 29C is disposed between the second top gate electrode 29G1 and the second bottom gate electrode 29G2 with respect to the upper-bottom direction. The first TFTs 27 and the second TFTs 29 have a double gate structure. With the double gate structure, the first semiconductor portions 27C and the second semiconductor portions 29C can stably include channel sections. However, the first TFTs 27 and the second TFTs 29 may have a top gate structure and the first TFTs 27 may only include the first top gate electrodes 27G1 and the second TFTs 29 may only include the second top gate electrodes 29G1.

The array substrate 21 includes a substantially transparent glass substrate 21GS (one example of an insulating substrate) and various films formed in layers on the glass substrate 21GS. The glass substrate 21GS includes alkali-free glass as main material. The array substrate 21 includes two types of TFTs including the first TFTs 27 and the second TFTs 29. The first semiconductor portions 27C of the first TFTs 27 and the second semiconductor portions 29C of the second TFTs 29 are disposed in different layers. On the glass substrate 21GS of the array substrate 21, the following films are disposed on top of each other in the following order from the lowest layer (the grass substrate GS side): a light blocking portions 40, a basecoat film 41, a first gate metal film including portions that are configured as the first bottom gate electrodes 27G2, the second bottom gate electrodes 29G2, and the bottom gate lines 25B, a first insulating film 31, the first semiconductor film including portions that are configured as the first semiconductor portions 27C, a second insulating film 32, the second semiconductor film including portions that are configured as the second semiconductor portions 29C, a third insulating film 33, a second gate metal film including portions that are configured as the first top gate electrodes 27G1, the second top gate electrodes 29G1, and the top gate lines 25A, a fourth insulating film 34, a source metal film including portions that are configured as the first source electrodes 27S, the second source electrodes 29S, the first drain electrodes 27D, the second drain electrodes 29D, and the source lines 26, a planarization film 37, a first transparent conductive film including portions that are configured as the pixel electrodes 28, a fifth insulation film 38, and a second transparent conductive film including a portion that is configured as a common electrode 39. The common electrode 39 is not included in FIGS. 4 and 5 to obviously illustrate other components.

Each of the light blocking portion 40, the first gate metal film, the second gate metal film, and the source metal film is a single-layer film made of one kind of metal, or a multilayer film made of different kinds of metals, or alloy, and has electrically conductive properties and light blocking properties.

The first transparent conductive film and the second transparent conductive film are made of transparent conductive material such as indium tin oxide (ITO) and indium zinc oxide (IZO).

Each of the basecoat film 41, the first insulating film 31, the second insulating film 32, the third insulating film 33, the fourth insulating film 34, and the fifth insulating film 38 is made of inorganic material (inorganic resin material) and may be a single-layer film or a multilayer film including SiOₓ (silicon oxide) and SiNₓ (silicon nitride).

The planarization film 37 is made of organic material (organic resin material) such as PMMA (acrylic resin). The planarization film 37 normally has a film thickness greater than that of other insulation films made of inorganic material.

The first semiconductor film and the second semiconductor film are made of oxide semiconductor material. The oxide semiconductor material has higher electron mobility than the amorphous silicon semiconductor material. The oxide semiconductor material has higher resistance value with no voltage being applied (OFF state) compared to polysilicon semiconductor material. Semiconductor doping (adding of impurities to the intrinsic semiconductor) is not necessary for the oxide semiconductor material unlike polysilicon semiconductor material.

The first semiconductor film and the second semiconductor film of this embodiment have a same thickness and a same composition but may have different thicknesses and compositions as will be described later. By using the oxide semiconductor material, the two semiconductor films have different composition ratios and deoxygenation and hydrogen diffusion can be easily controlled.

Oxide semiconductor material that includes at least one kind of metallic elements out of In, Ga, and Zn may be used as the oxide semiconductor material. The oxide semiconductor material may be amorphous or crystalline and may be an In—Ga—Zn—O semiconductor (for example, In—Ga—Zn oxide). Examples of the oxide semiconductor material may include an In—Sn—Zn—O semiconductor (for example, In₂O₃—SnO₂—ZnO; InSnZnO), an In—W—Zn—O semiconductor, an In—W—Sn—Zn—O semiconductor, an In—Al—Zn—O semiconductor, an In—Al—Sn—Zn—O semiconductor, a Zn—O semiconductor, an In—Zn—O semiconductor, a Zn—Ti—O semiconductor, a Mg—Zn—O semiconductor, an In—Ga-Sn-O semiconductor, an In—Ga—O semiconductor, a Zr—In—Zn—O semiconductor, a Hf—In—Zn—O semiconductor, an Al—Ga—Zn—O semiconductor, a Ga—Zn—O semiconductor, and an In—Ga—Zn—Sn—O semiconductor.

As illustrated in FIG. 8, the second insulating film 32 is disposed between the first semiconductor portions 27C, which are portions of the first semiconductor film, and the second semiconductor portions 29C, which are portions of the second semiconductor film. The second insulating film 32 insulates the first semiconductor portions 27C from the second semiconductor portions 29C. As illustrated in FIG. 6, the second insulating film 32 and the third insulating film 33 are configured as the gate insulating films disposed between the first semiconductor portions 27C and the first top gate electrodes 27G1 of the first TFTs 27. The first insulating film 31 is configured as the gate insulating film disposed between the first semiconductor portions 27C and the first bottom gate electrodes 27G2. As illustrated in FIG. 7, the third insulating film 33 is configured as the gate insulating film disposed between the second semiconductor portions 29C and the second top gate electrodes 29G1 of the second TFTs 29. The first insulating film 31 and the second insulating film 32 are configured as the gate insulating films disposed between the second semiconductor portions 29C and the second bottom gate electrodes 29G2. Therefore, the number of layers (the film thickness) of the gate insulating films between the gate electrode and the semiconductor portion differs between the first TFT 27 and the second TFT 29.

The pixel electrodes 28 are portions of the first transparent conductive film. As illustrated in FIGS. 6 and 7, the pixel electrodes 28 include contact portions 28A that are through the planarization films 37. Some of the contact portions 28A are connected to the first drain electrodes 27D and other contact portions 28A are connected to the second drain electrodes 29D.

The common electrode 39 is a portion of the first transparent conductive film. The common electrode 39 is formed to overlap all the pixel electrodes 28 via the fifth insulating film 38. The common electrode 39 is included in a layer upper than the layer including the pixel electrodes 28. The common electrode 39 includes slits 39A in portions overlapping the pixel electrodes 28, respectively. The common electrode 39 is supplied with a common potential signal of a common potential (a reference potential). With the pixel electrode 28 being charged with a potential based on the image signal transmitted to the source line 26 according to the driving of the first TFT 27 or the second TFT 29, a potential difference occurs between the pixel electrode 28 and the common electrode 39. Then, a fringe electric field (an oblique electric field) is created between an opening edge of the slit 39A of the common electrode 39 and the pixel electrode 28. The fringe electric field includes a component parallel to the plate surface of the array substrate 21 and a component normal to the plate surface of the array substrate 21. With the fringe electric field, orientations of the liquid crystal molecules included in the liquid crystal layer 22 can be controlled. Namely, the liquid crystal panel 11 according to this embodiment operates in the fringe field switching (FFS) mode.

As illustrated in FIGS. 6 to 8, in the display area AA, the light blocking portion 40 is disposed to overlap at least an entire area of the first bottom gate electrode 27G2 and an entire area of the second bottom gate electrode 29G2. The light blocking portion 40 blocks the light supplied from the backlight unit to the channel sections of the first semiconductor portion 27C and the second semiconductor portion 29C from the lower layer side. As a result, the characteristics of the first TFTs 27 and the second TFTs 29 are less likely to change due to the supply of the light to the channel sections.

The array substrate 21 having the above-described configuration is produced by forming the various kinds of films on the glass substrate 21Gs with the known photolithography method with patterning in the order previously described. Each of the films may be heated at appropriate timing. An alignment film is disposed with coating on an uppermost layer of the array substrate 21 (a layer closest to the liquid crystal layer 22) to cover the layered films formed with photolithography.

In this embodiment, with patterning, a film is processed with a general photolithography method. Specifically, with patterning, the following steps are performed. A photoresist film is formed on a film to be processed, the photoresist film is exposed with an exposure device via a photomask having a predefined pattern and developing the photoresist film, and the film to be processed is subjected to etching via the developed photoresist film.

Generally, a smallest size of the layout pattern used for patterning with photolithography is determined by the resolution of the photoresist film. To increase the resolution of the liquid crystal panel 11, the interval between the pixels needs to be decreased to be smaller than the limit value of the resolution of the photoresist film.

According to this embodiment, with the adjacent semiconductor portions (the first semiconductor portions 27C and the second semiconductor portions 29C) being included in the different layers (the first semiconductor film and the second semiconductor film), the interval L3 between the adjacent semiconductor portions can be decreased to be smaller than the smallest dimension of the layout pattern that is formed with photolithography. More specifically, with the interval L1 between the first semiconductor portions 27C and the interval L2 between the second semiconductor portions 29C being the smallest values obtained with the smallest dimension of the layout pattern, the interval L3 between the adjacent semiconductor portions can be smaller than the intervals L1 and L2.

On the other hand, the first gate electrodes 27G of the first TFTs 27 and the second gate electrodes 29G of the second TFTs 29 are included in the same layer, the first source electrodes 27S and the second source electrodes 29S are included in the same layer, and the first drain electrodes 27D and the second drain electrodes 29D are included in the same layer (the first gate metal film, the second metal film, the source metal film). As a result, the array substrate 21 including the pixels with small intervals can be obtained without increasing the number of layers of thin films.

### Second Embodiment

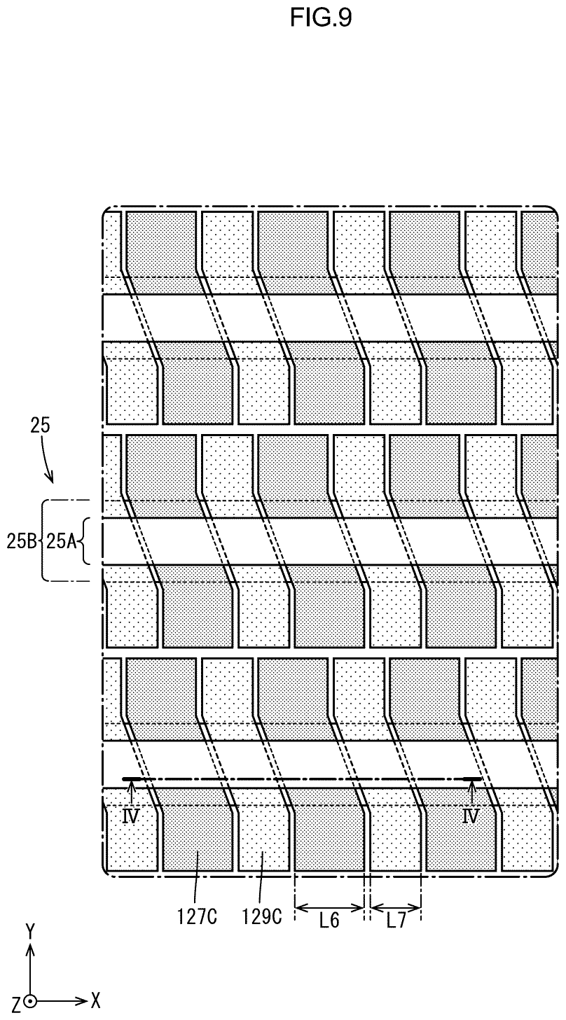

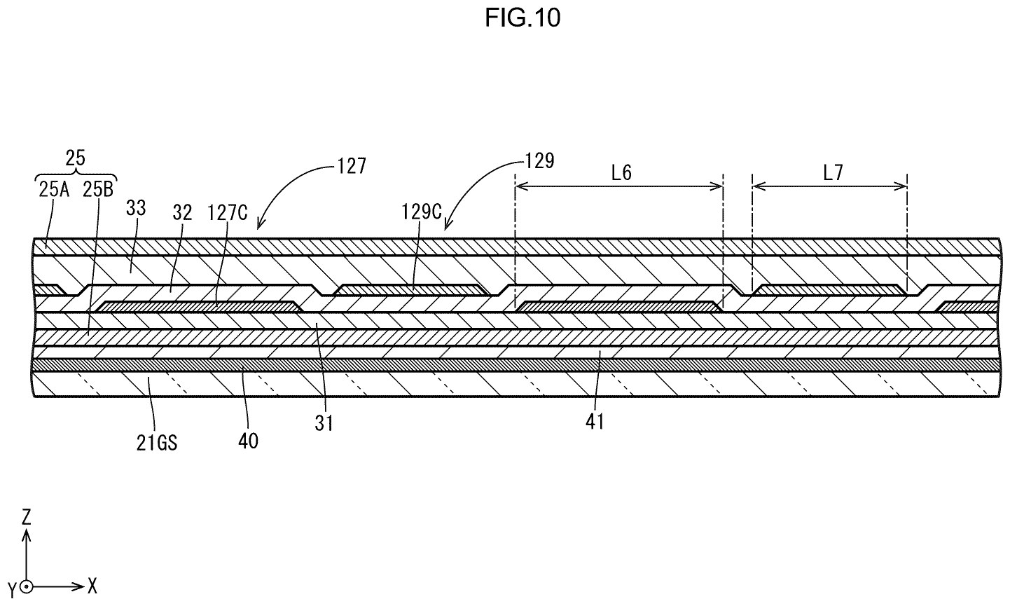

First semiconductor portions 127C and second semiconductor portions 129C according to a second embodiment will be described with reference to FIGS. 9 and 10. Between the first semiconductor portions 127C and the second semiconductor portions 129C, at least one of a dimension extending in the X-axis direction (a width), a thickness, and a composition differs. Components of the second embodiment same as those of the first embodiment are referred to with same reference numbers. Configurations, operations, and effects similar to those of the first embodiment may not be described.

The second insulating film 32 is disposed between the first semiconductor portions 127C, which are portions of the first semiconductor film, and the second semiconductor portions 129C, which are portions of the second semiconductor film. The number of gate insulating films (a film thickness of the gate insulating films) disposed between the first semiconductor portion 127C and the first gate electrode 27G differs from the number of gate insulating films (a film thickness of the gate insulating films) disposed between the second semiconductor portion 129C and the second gate electrode 29G. Accordingly, a distance between the first gate electrode 27G and the first semiconductor portion 127C differs from a distance between the second gate electrode 29G and the second semiconductor portion 129C. Therefore, difference may be caused in the TFT characteristics between first TFTs 127 and second TFTs 129. More specifically, the distance between the first top gate electrode 27G1 and the first semiconductor portion 127C is greater than the distance between the second top gate electrode 29G1 and the semiconductor portion 129C. Therefore, with a same gate voltage being applied to the first semiconductor portion 127C and the second semiconductor portion 129C, the ion concentration of the second semiconductor portion 129C may be higher than that of the first semiconductor portion 127C.

At least one of the dimension extending in the X-axis direction (a channel width), the thickness, and the composition may differs between the first semiconductor portions 127C and the second semiconductor portions 129C such that the difference in the TFT characteristics is less likely to be caused. For example, with the first semiconductor portions 127C and the second semiconductor portions 129C being made of In—Sn—Zn—O semiconductor material, the content of In in the first semiconductor portions 127C is increased to be greater than the content of In in the second semiconductor portions 129C. More specifically, the film forming conditions or the target material (base material) for forming the films may be changed when forming the first semiconductor film and forming the second semiconductor film, or deoxygenation and hydrogen diffusion may be adjusted for each of the first semiconductor film and the second semiconductor film according to the film forming conditions of the second insulating film 32 and the third insulating film 33 that are contacted with the first semiconductor film and the second semiconductor film. As illustrated in FIGS. 9 and 10, the X-axis dimension L6 of the first semiconductor portions 127C may be increased to be greater than the X-axis dimension L7 of the second semiconductor portions 129C or the thickness of the first semiconductor portions 127C may be reduced to be smaller than the thickness of the second semiconductor portions 129C.

### Third Embodiment

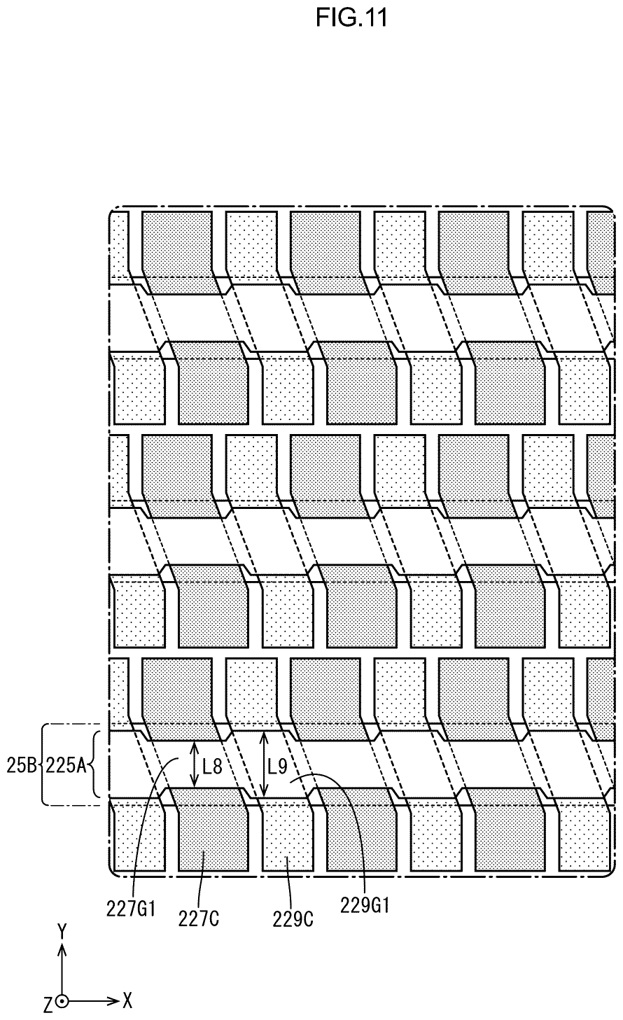

First top gate electrodes 227G1 and second top gate electrodes 229G1 according to a third embodiment will be described with reference to FIG. 11. Unlike the second embodiment, the first top gate electrodes 227G1 have a Y-axis dimension that is different from a Y-axis dimension of the second top gate electrodes 229G1. Components of the third embodiment same as those of the first embodiment and the second embodiment are referred to with same reference numbers. Configurations, operations, and effects similar to those of the first embodiment and the second embodiment may not be described.

The dimension extending in the Y-axis direction (a channel length) may preferably differ between the first top gate electrodes 227G1 and the second top gate electrodes 229G1 such that the difference in the TFT characteristics is less likely to be caused. For example, as illustrated in FIG. 11, top gate lines 225A are formed with patterning such that the Y-axis dimension L9 of the second top gate electrodes 229G1 is greater than the Y-axis dimension L8 of the second top gate electrodes 227G1.

### Other Embodiments

The technology described herein is not limited to the embodiments described above and illustrated by the drawings. For example, the following embodiments will be included in the technical scope of the present technology.

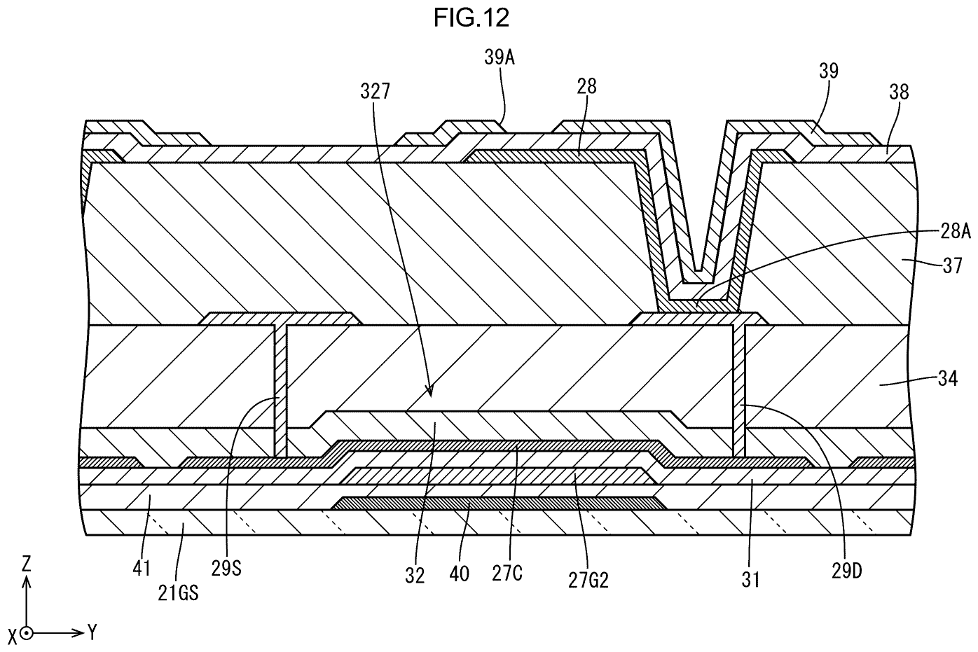

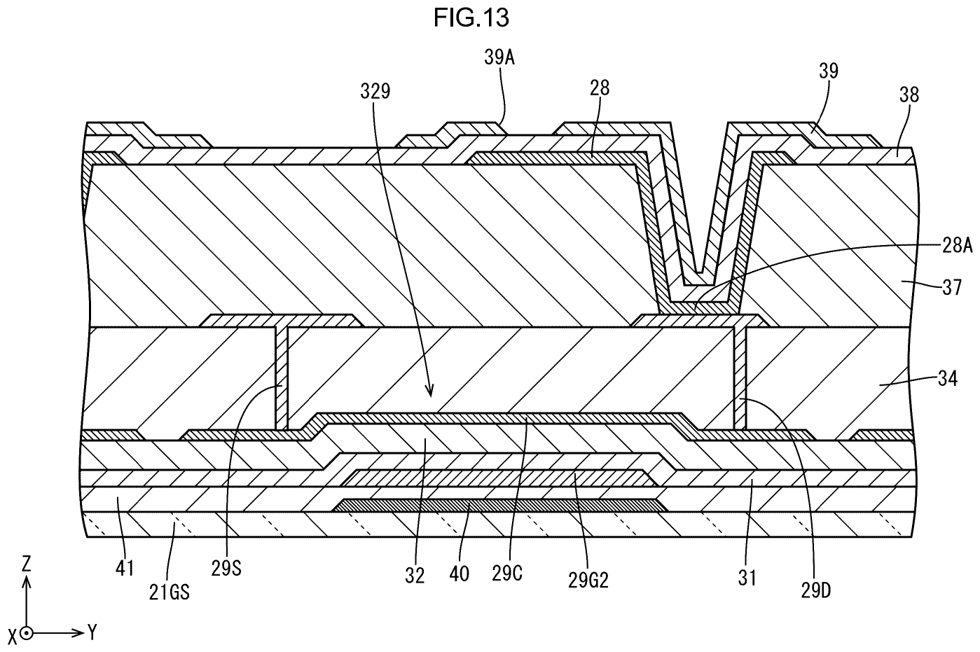

(1) As illustrated in FIGS. 12 and 13, first TFTs 327 and second TFTs 329 that have a bottom gate structure and include only the bottom gate electrodes 27G2, 29G2 may be used.

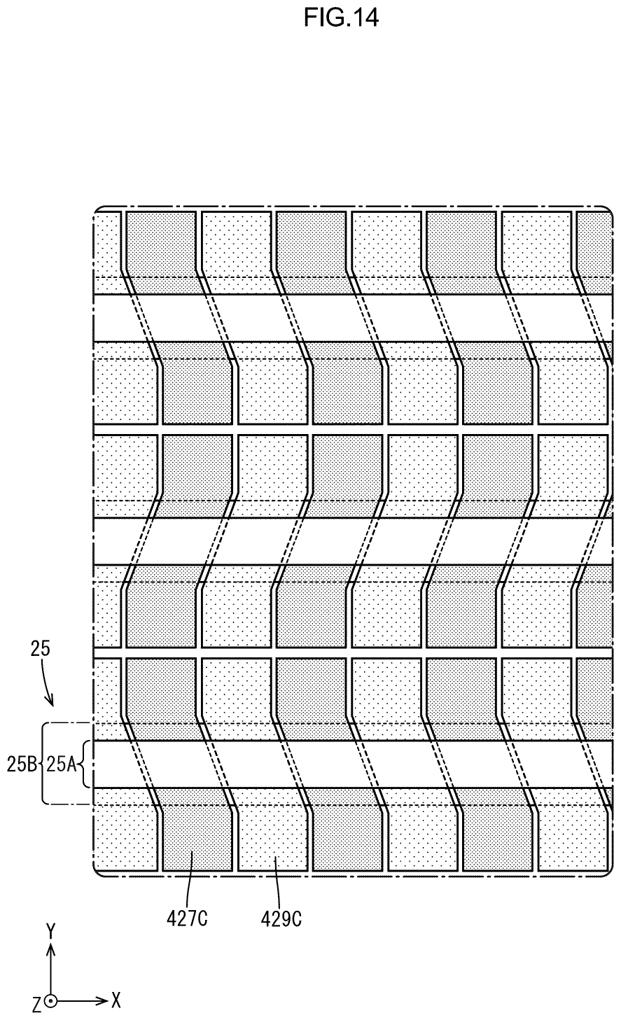

(2) As illustrated in FIG. 14, first semiconductor portions 427C having different planar shapes (orientations of the patterns) may be alternately arranged in the Y-axis direction and second semiconductor portions 429C having different planar shapes may be alternately arranged in the Y-axis direction.

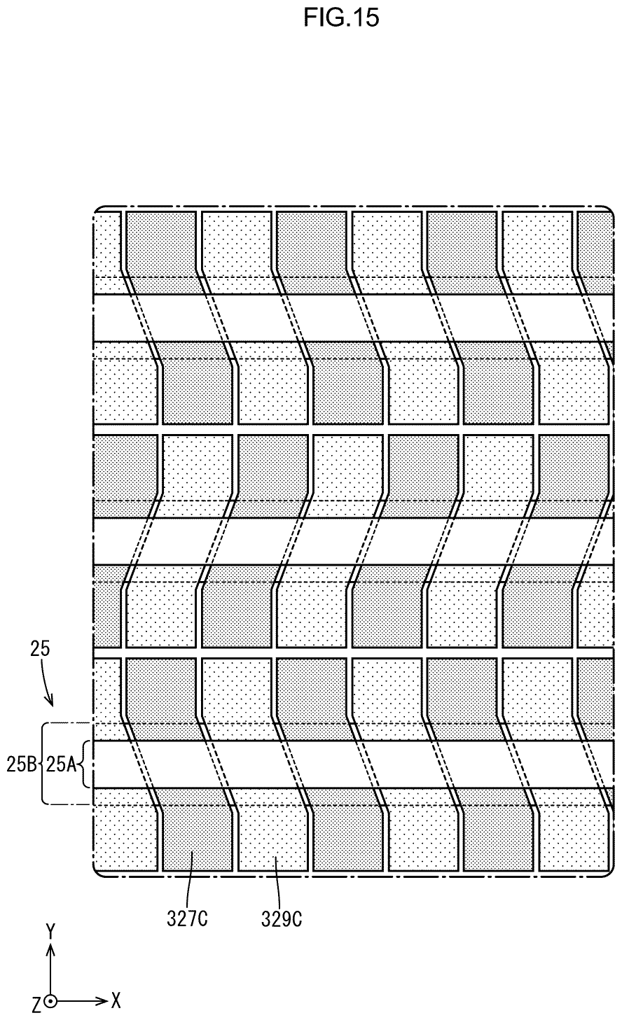

(3) As illustrated in FIG. 15, first semiconductor portions 327C and second semiconductor portions 329C may be alternately arranged in the Y-axis direction. Namely, the second semiconductor portion 329C is disposed between two adjacent first semiconductor portions 327C that are arranged in the Y-axis direction in a plan view. Accordingly, the first TFTs and the second TFTs are arranged alternately arranged in the X-axis direction and the Y-axis direction.

(4) The array substrate 21 may not necessarily have the layered structure and the layout pattern illustrated in the drawings. For example, the array substrate 21 may include lines for a touch panel function.

(5) The TFTs included in the first circuits 14A and the second circuit 14B arranged in the non-display area NAA may include a semiconductor film made of polysilicon semiconductor material such as low temperature polycrystalline silicon (LTPS)

(6) The display mode of the liquid crystal panel 11 may not be the FFS mode but may be other modes such as the IPS (in plane switching) mode. The common electrode 39 may be included in the opposed substrate 20 according to the display mode.

(7) The present technology may be applied to different types of display panels such as organic electro luminescence display panels.

1. An array substrate comprising:
an insulating substrate;
gate lines disposed on an upper layer side of the insulating substrate and extending in a first direction, the gate lines being portions of a gate metal film;
source lines extending in a second direction that crosses the first direction, the source lines being portions of a source metal film; and
first TFTs and second TFTs arranged alternately in the first direction in a plan view,
the first TFTs including
first semiconductor portions that are portions of a first semiconductor film and arranged in the first direction, first gate electrodes that are portions of the gate metal film, and
first source electrodes and first drain electrodes that are portions of the source metal film; and
the second TFTs including
second semiconductor portions that are portions of a second semiconductor film that is disposed in a layer upper than a layer including the first semiconductor film via an insulating film, the second semiconductor portions and the first semiconductor portions being arranged alternately in the first direction,
second gate electrodes that are portions of the gate metal film, and
second source electrodes and second drain electrodes that are portions of the source metal film.

2. The array substrate according to claim 1, wherein
the first semiconductor portions have a first dimension extending in the first direction,
the second semiconductor portions have a second dimension extending in the first direction, and
the first dimension is different from the second dimension.

3. The array substrate according to claim 1, wherein the second semiconductor portions have a thickness that is different from a thickness of the first semiconductor portions.

4. The array substrate according to claim 1, wherein the second semiconductor portions are made of material that has a composition different from a composition of material of the first semiconductor portions.

5. The array substrate according to claim 1, wherein
the first semiconductor portions have a third dimension extending in the second direction,
the second semiconductor portions have a fourth dimension extending in the second direction, and
the third dimension is different from the fourth dimension.

6. The array substrate according to claim 1, wherein
the first TFTs and the second TFTs are arranged alternately in the second direction in a plan view, and
one of the second semiconductor portions is disposed between two of the first semiconductor portions that are adjacent to each other in the second direction in a plan view.

7. The array substrate according to claim 1, wherein the gate metal film is included in a layer upper than layers including the first semiconductor film and the second semiconductor film.

8. The array substrate according to claim 1, wherein the gate metal film is included in a layer lower than layers including the first semiconductor film and the second semiconductor film.

9. The array substrate according to claim 1, wherein the first semiconductor film and the second semiconductor film are made of oxide semiconductor material that includes at least one kind of metallic elements of In, Ga, and Zn.

10. The array substrate according to claim 9, wherein
the first semiconductor portions have a first dimension extending in the first direction,
the second semiconductor portions have a second dimension extending in the first direction, and
the first dimension is greater than the second dimension.

11. The array substrate according to claim 9, wherein a content of the at least one kind of metallic elements of In, Ga, and Zn in the first semiconductor film is greater than that in the second semiconductor film.
